(19) United States
(12) Patent Application Publication
(10) Pub. No.: US 2019/0355638 A1
(43) Pub. Date: Nov. 21, 2019

(54) HEAT-CURABLE MALEIMIDE RESIN COMPOSITION FOR SEMICONDUCTOR ENCAPSULATION AND SEMICONDUCTOR DEVICE

(71) Applicant: SHIN-ETSU CHEMICAL CO., LTD., Tokyo (JP)

(72) Inventors: Yoshihiro Tsutsumi, Annaka-shi (JP); Naoyuki Kushihara, Annaka-shi (JP); Hiroki Oishi, Annaka-shi (JP); Yoshihira Hamamoto, Annaka-shi (JP); Yuki Kudo, Annaka-shi (JP)

(73) Assignee: SHIN-ETSU CHEMICAL CO., LTD., Tokyo (JP)

(21) Appl. No.: 16/407,720

(22) Filed: May 9, 2019

(30) Foreign Application Priority Data
May 18, 2018 (JP) 2018-096042

(51) Int. Cl. H01L 23/29; C08L 63/00; C08L 79/08; C08K 3/013; C08L 61/04

(52) U.S. Cl. CPC H01L 23/295; C08L 63/00; C08J 3/247; C08K 3/013; C08L 61/04; C08L 79/08

(57) ABSTRACT

Provided are a heat-curable maleimide resin composition capable of yielding a cured product superior in tracking resistance; and a semiconductor device encapsulated by the cured product of such resin composition. The heat-curable maleimide resin composition for semiconductor encapsulation contains:
(A) a maleimide compound being solid at 25° C., and having, per molecule, at least one dimer acid backbone, at least one linear alkylene group having not less than 6 carbon atoms, and at least two maleimide groups;
(B) an inorganic filler; and
C) a curing accelerator.

### BACKGROUND OF THE INVENTION

### Field of the invention

The present invention relates to a heat-curable maleimide resin composition for semiconductor encapsulation; and a semiconductor device using the same.

### Background art

Nowadays, mainstream semiconductor devices are resin-encapsulated diodes, transistors, IC, LSI and VLSI. Here, since epoxy resins are superior to other heat-curable resins in, for example, moldability, adhesion, electrical properties and mechanical properties, semiconductors are usually to be encapsulated by epoxy resin compositions. In recent years, semiconductor devices are more often used under a high-voltage power environment such as those involving an automobile, a train, wind power generation and solar power generation. In this way, an excellent tracking resistance (high CTI (Comparative Tracking Index)) is desired.

Further, in the current situation where the packages used are becoming lighter, thinner, shorter and smaller, and it has thus become more difficult to even secure a sufficient insulation distance(s), general epoxy resin compositions used so far do not necessarily exhibit sufficient electrical properties, especially insulation properties. This seems to be attributed to the phenyl groups in epoxy resins.

JP-A-2005-213299 discloses a composition having a dicyclopentadiene-type epoxy resin as its essential component for the purpose of improving a tracking resistance via the epoxy resin itself. However, in terms of improving the tracking resistance, it is not sufficient to merely employ a di cyclopentadiene-type epoxy resin.

JP-A-2008-143950, JP-A-2009-275146, JP-A-2013-112710 and JP-A-2013-203865 disclose compositions intended to improve the tracking resistance by adding to an epoxy resin composition, for example, a metallic hydroxide, a spherical silicone powder, silicone rubber or a spherical cristobalite. However, it turned out that a heat resistance and fluidity had declined, and the tracking resistance was still insufficient i.e. the tracking resistance and other properties were not satisfactory.

JP-A-2006-299246 and JP-A-2017-145366 disclose mixing a maleimide compound into an epoxy resin composition so as to improve a glass-transition temperature (Tg), and obtain a cured product superior in high-temperature reliability, moisture resistance reliability and dielectric property. However, since a cured product in such case tends to exhibit a higher elastic modulus, a semiconductor element(s) will be subjected to a high level of stress, which results in a need for further improvements.

### SUMMARY OF THE INVENTION

Thus, it is an object of the present invention to provide a heat-curable maleimide resin composition capable of yielding a cured product superior in tracking resistance; and a semiconductor device encapsulated by the cured product of such resin composition. Further, it is also an object of the present invention to provide a resin composition capable of yielding a cured product exhibiting an excellent dielectric property, a low relative permittivity and a low dielectric tangent; and a semiconductor device encapsulated by the cured product of such resin composition.

The inventors of the present invention diligently conducted a series of studies to solve the aforementioned problems, and completed the invention as follows. That is, the inventors found that the above objectives could be achieved by the following heat-curable maleimide resin composition.

Specifically, the present invention is to provide the following heat-curable maleimide resin composition for semiconductor encapsulation; a cured product of such composition; and a semiconductor device encapsulated by such cured product.

[1]

A heat-curable maleimide resin composition for semiconductor encapsulation, comprising:

(A) a maleimide compound being solid at 25° C., and having, per molecule, at least one dimer acid backbone, at least one linear alkylene group having not less than 6 carbon atoms, and at least two maleimide groups;

(B) an inorganic filler; and

(C) a curing accelerator.

[2]

The heat-curable maleimide resin composition for semiconductor encapsulation according to [1], further comprising an epoxy resin as a component (D).

[3]

The heat-curable maleimide resin composition for semiconductor encapsulation according to [2], further comprising a curing agent as a component (E).

[4]

The heat-curable maleimide resin composition for semiconductor encapsulation according to [3], wherein the curing agent as the component (E) is a phenolic resin and/or a benzoxazine resin.

[5]

The heat-curable maleimide resin composition for semiconductor encapsulation according to any one of [1] to [4], wherein the maleimide compound as the component (A) is represented by the following general formulae (1) and/or (2):

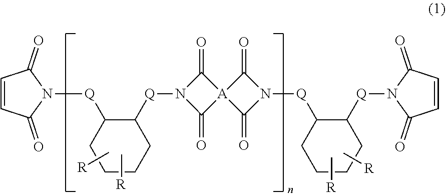

wherein A represents a tetravalent organic group having an aromatic ring or aliphatic ring; Q represents a linear alkylene group having not less than 6 carbon atoms; each R independently represents a linear or branched alkyl group having not less than 6 carbon atoms; n represents a number of 1 to 10,

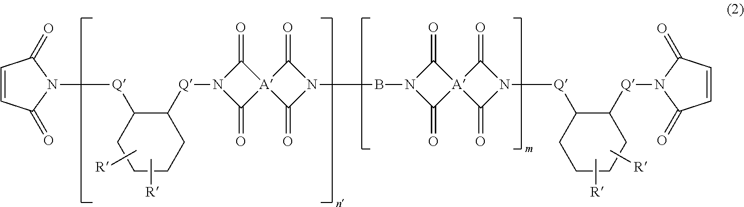

wherein A′ represents a tetravalent organic group having an aromatic ring or aliphatic ring; B represents an alkylene chain having 6 to 18 carbon atoms and a divalent aliphatic ring that may contain a hetero atom; Q′ represents a linear alkylene group having not less than 6 carbon atoms; each R′ independently represents a linear or branched alkyl group having not less than 6 carbon atoms; n′ represents a number of 1 to 10; m represents a number of 1 to 10.
[6]

The heat-curable maleimide resin composition for semiconductor encapsulation according to [5], wherein each of A in the general formula (1) and A′ in the general formula (2) is represented by any one of the following structures:

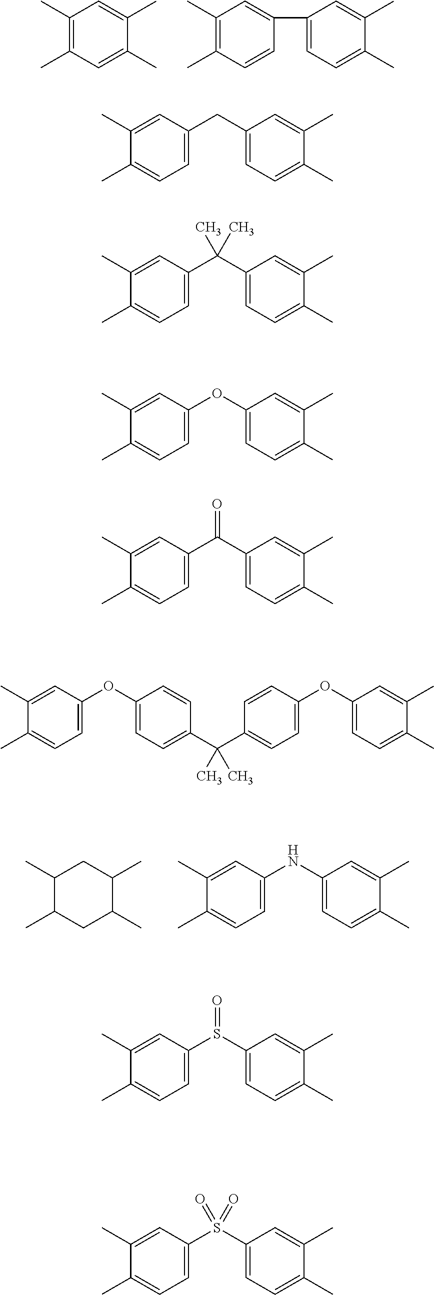

wherein bonds in the above structural formulae that are yet unbonded to substituent groups are to be bonded to carbonyl carbons forming cyclic imide structures in the general formulae (1) and (2).
[7]

A semiconductor device encapsulated by a cured product of the heat-curable maleimide resin composition for semiconductor encapsulation according to any one of [1] to [6].

Since the cured product of the heat-curable maleimide resin composition of the invention which is used for semiconductor encapsulation has a high tracking resistance and an excellent dielectric property, it is useful as a material for encapsulating a semiconductor device.

### DETAILED DESCRIPTION OF THE INVENTION

The present invention is described in greater detail hereunder.

### (A) Maleimide Compound

A component (A) is a maleimide compound being solid at 25° C., and having, per molecule, at least one dimer acid backbone, at least one linear alkylene group having not less than 6 carbon atoms, and at least two maleimide groups. By possessing a linear alkylene group(s) having not less than 6 carbon atoms, not only a superior dielectric property can be imparted, but a phenyl group content ratio can be reduced such that a tracking resistance can be improved. Further, by having a linear alkylene group(s), a cured product with a lower elasticity can be obtained, which is effective in reducing a stress applied to a semiconductor device by the cured product.

Particularly, it is preferred that the maleimide compound as the component (A) be that represented by the following general formulae (1) and/or (2).

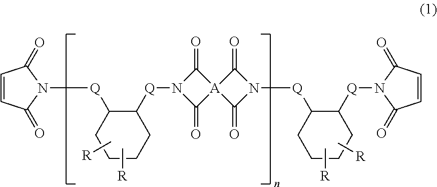

In the general formula (1), A represents a tetravalent organic group having an aromatic ring or aliphatic ring. Q represents a linear alkylene group having not less than 6 carbon atoms. Each R independently represents a linear or branched alkyl group having not less than 6 carbon atoms. n represents a number of 1 to 10.

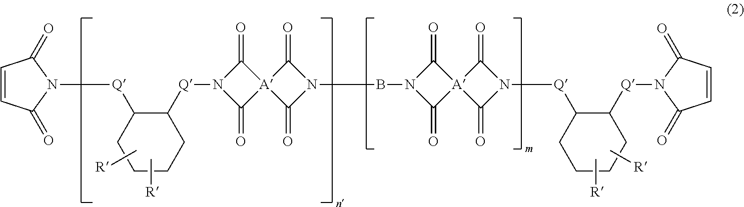

In the general formula (2), A′ represents a tetravalent organic group having an aromatic or aliphatic ring. B represents an alkylene chain having 6 to 18 carbon atoms and a divalent aliphatic ring that may contain a hetero atom. Q′ represents a linear alkylene group having not less than 6 carbon atoms. Each R′ independently represents a linear or branched alkyl group having not less than 6 carbon atoms. n′ represents a number of 1 to 10. m represents a number of 1 to 10.)

While Q in the formula (1) and Q′ in the formula (2) are linear alkylene groups, and the number of carbon atoms therein is not less than 6 each, it is preferred that such number be 6 to 20, more preferably 7 to 15. Further, while the number of carbon atoms in each R in the formula (1) and each R′ in the formula (2) is not less than 6, it is preferred that such number be 6 to 12; and R and R′ may be either linear or branched alkyl groups.

Each of A in the formula (1) and A′ in the formula (2) represents a tetravalent organic group having an aromatic or aliphatic ring. Particularly, it is preferred that the tetravalent organic group be that represented by any one of the following structural formulae:

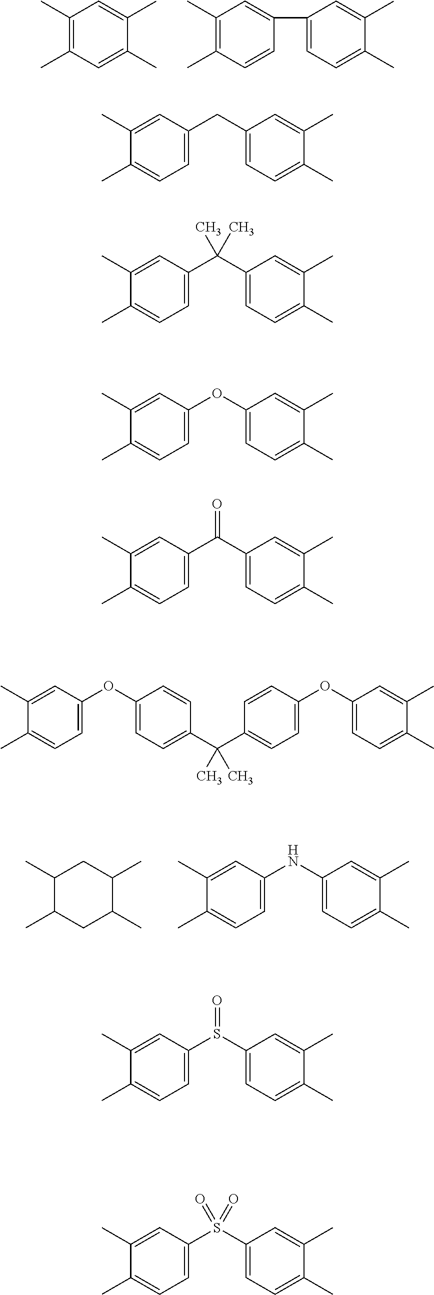

Here, bonds in the above structural formulae that are yet unbonded to substituent groups are to be bonded to carbonyl carbons forming cyclic imide structures in the general formulae (1) and (2).

Further, B in the formula (2) represents an alkylene chain having 6 to 18 carbon atoms and a divalent aliphatic ring that may contain a hetero atom. It is preferred that the alkylene chain have 8 to 15 carbon atoms. It is preferred that B in the formula (2) be an aliphatic group-containing alkylene chain represented by any one of the following structural formulae.

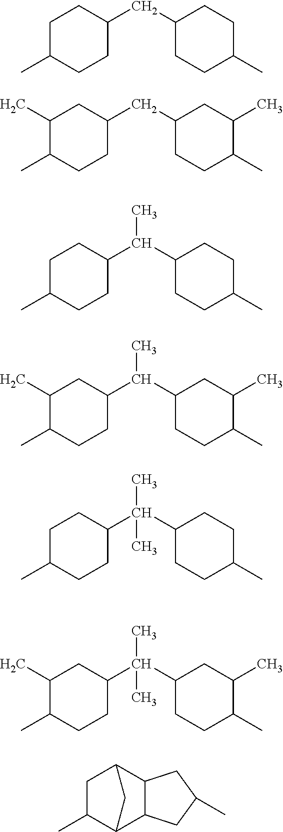

In the above formulae, bonds that are yet unbonded to substituent groups are to be bonded to nitrogen atoms forming cyclic imide structures in the general formula (2).

n in the formula (1) represents a number of 1 to 10, preferably 2 to 7. n′ in the formula (2) represents a number of 1 to 10, preferably 2 to 7. m in the formula (2) represents a number of 1 to 10, preferably 2 to 7.

There are no particular restrictions on a weight-average molecular weight (Mw) of the maleimide compound as the component (A), as long as the weight-average molecular weight is in a range by which the compound may remain solid at room temperature. However, it is preferred that a weight-average molecular weight thereof in terms of polystyrene that is measured by gel permeation chromatography (GPC) be 2,000 to 50,000, more preferably 2,500 to 40,000, and even more preferably 3,000 to 20,000. When such molecular weight is not lower than 2,000, the maleimide compound obtained will solidify easily. When such molecular weight is not higher than 50,000, a favorable moldability can be achieved in a sense that there will be no concern that the fluidity of the composition obtained may decrease due to an excessively high viscosity thereof.

Here, the notation “Mw” in the present invention refers to a weight-average molecular weight that is measured by GPC under the following conditions, and is expressed in terms of polystyrene as a reference material.
Measurement condition
Developing solvent: tetrahydrofuran
Flow rate: 0.35 mL/min
Detector: RI
Column: TSK-GEL H type (by Tosoh Corporation)
Column temperature: 40° C.
Sample injection amount: 5 μL

As the maleimide compound as the component (A), there may be used commercially available products such as BMI-2500, BMI-2560, BMI-3000, BMI-5000 and BMI-6100 (all of which are produced by Designer Molecules Inc.).

Further, only one kind of a maleimide compound may be used singularly, or multiple kinds of maleimide compounds may be used in combination.

It is preferred that the component (A) be contained in the composition of the present invention, by an amount of 8 to 80% by mass, more preferably 10 to 85% by mass, and even more preferably 12 to 75% by mass.

(B) Inorganic filler

An inorganic filler as a component (B) is added to improve the strength of the cured product of the heat-curable maleimide resin composition of the invention. As the inorganic filler as the component (B), there may be used those normally added to an epoxy resin composition or a silicone resin composition. For example, there may be used silicas such as a spherical silica, a molten silica and a crystalline silica; alumina; silicon nitride; aluminum nitride; boron nitride; a glass fiber; and a glass particle(s). In addition, there may also be used a fluorine resin-containing or -coated filler for the purpose of improving the dielectric property.

While there are no particular restrictions on the average particle size and shape of the inorganic filler as the component (B), the average particle size thereof is normally 0.1 to 40 μm. As the component (B), a spherical silica having an average particle size of 0.5 to 40 μm is preferably used. Here, the average particle size is defined as a value obtained as a mass average value D₅₀ (or median diameter) in a particle size distribution measurement that is carried out by a laser diffraction method.

Further, from the perspective of achieving a higher fluidity of the composition obtained, inorganic fillers with particle sizes from multiple ranges may be used in combination. In such case, it is preferred that there be combined spherical silicas with particle sizes belonging to a microscopic range of 0.1 to 3 μm, an intermediate range of 3 to 7 μm, and a coarse range of 10 to 40 μm. In order to achieve an even higher fluidity, it is preferred that there be used a spherical silica with an even larger average particle size.

It is preferred that the inorganic filler as the component (B) be employed in an amount of 300 to 1,000 parts by mass, particularly preferably 400 to 800 parts by mass, per a sum total of 100 parts by mass of the components (A), (D) and (E). When such amount is smaller than 300 parts by mass, there exists a concern that a sufficient strength may not be achieved. When such amount is greater than 1,000 parts by mass, unfilling defects due to an increase in viscosity may occur, and a flexibility may be lost, which may then cause failures such as peeling in an element(s). Here, it is preferred that this inorganic filler be contained in an amount of 10 to 90% by mass, particularly preferably 20 to 85% by mass, with respect to the whole composition.

### (C) Curing Accelerator

The heat-curable maleimide resin composition of the present invention contains a curing accelerator as a component (C). This curing accelerator is used not only to promote the reaction of the maleimide compound as the component (A), but also to, for example, promote the reaction between a later-described epoxy resin as a component (D) and a later-described curing agent for epoxy resin as a component (E), and even promote the reactions among the components (A), (D) and (E). Here, there are no particular restrictions on the kind(s) of such curing accelerator.

As a curing accelerator (polymerization initiator) for only promoting the reaction of the component (A), while there exists no particular restrictions on such curing accelerator, preferred is a heat radical polymerization initiator considering the fact that molding is to be performed by heating. Here, there are no restrictions on the kind(s) of such heat radical polymerization initiator. Specific examples of the heat radical polymerization initiator include dicumylperoxide, t-hexyl hydroperoxide, 2,5-dimethyl-2,5-bis(t-butylperoxy)hexane, α, α′-bis(t-butylperoxy)diisopropylbenzene, t-butylcumyl peroxide and di-t-butylperoxide.

The usage of a photo-radical polymerization initiator is not particularly preferable in terms of handling property and storability.

As a curing accelerator (catalyst) employed when the later-described components (D) and/or (E) are contained, there are no particular restrictions on such curing accelerator as long as the curing accelerator is capable of promoting the curing reaction of a general epoxy resin composition. Examples of this catalyst include an amine-based compound such as 1,8-diazabicyclo[5,4, 0]-7-undecene; an organic phosphorous compound such as triphenylphosphine and tetraphenylphosphonium-tetraborate salt; and an imidazole compound such as 2-methylimidazole.

Any one of these curing accelerators may be used singularly, or two or more kinds of them may be used in combination. The component (C) is added in an amount of 0.1 to 10 parts by mass, preferably 0.2 to 5 parts by mass, per the sum total of 100 parts by mass of the components (A), (D) and (E).

Other than the above components, the following optional component(s) may also be added to the composition of the invention.

### (D) Epoxy Resin

An epoxy resin as the component (D) builds a three-dimensional bond by reaction with the later-described curing agent as the component (E) and the maleimide compound as the component (A), where the curing agent as the component (E) is capable of being employed to improve the fluidity and mechanical properties of the composition of the invention. While there are no particular restrictions on such epoxy resin as long as it has at least two epoxy groups in one molecule, preferred in terms of handling property are those that are solid at room temperature and more preferred are solids having either a melting point of 40° C. to 150° C. or a softening point of 50° C. to 160° C.

Specific examples of such epoxy resin include: a bisphenol A-type epoxy resin; a bisphenol F-type epoxy resin; a biphenol type epoxy resin such as 3,3′,5,5′-tetramethyl-4,4′-biphenol type epoxy resin and 4,4′-biphenol type epoxy resin; a phenol novolac-type epoxy resin; a cresol novolac-type epoxy resin; a bisphenol A novolac-type epoxy resin; a naphthalene diol-type epoxy resin; a trisphenylol methane-type epoxy resin; a tetrakisphenylol ethane-type epoxy resin; a phenol-biphenyl type epoxy resin; a dicyclopentadiene-type epoxy resin; an epoxy resin prepared by hydrogenating the aromatic rings in a phenol dicyclopentadiene novolac-type epoxy resin; a triazine derivative epoxy resin; and an alicyclic epoxy resin. Among these examples, a dicyclopentadiene-type epoxy resin is preferably used.

The component (D) is added in a manner such that a compounding ratio between the component (A) and the component (D), as a mass ratio, shall become (maleimide compound) : (epoxy resin)=100:0 to 10:90, preferably 100:0 to 15:85.

### (E) Curing Agent

Examples of the curing agent as the component (E) include a phenolic resin, an amine curing agent, an acid anhydride curing agent and a benzoxazine resin. A phenolic resin and/or a benzoxazine resin are preferred if the composition is intended as an encapsulation material for a semiconductor.

There are no particular restrictions on a phenolic resin as long as it is a compound having at least two phenolic hydroxyl groups in one molecule. However, preferred, in terms of handling property, are those that are solid at room temperature (25° C.), and more preferred are solids having either a melting point of 40° C. to 150° C. or a softening point of 50° C. to 160° C. Specific examples of such phenolic resin include a phenol novolac resin, a cresol novolac resin, a phenol aralkyl resin, a naphthol aralkyl resin, a terpene-modified phenolic resin and a dicyclopentadiene-modified phenolic resin. Any one of these phenolic resins may be used singularly, or two or more kinds of them may be used in combination. Here, a cresol novolac resin and a dicyclopentadiene-modified phenolic resin are preferably used.

The component (E) is added in a manner such that an equivalent ratio of the phenolic hydroxyl groups in the component (E) to the epoxy groups in the component (D) shall become 0.5 to 2.0, preferably 0.7 to 1.5. If such equivalent ratio is lower than 0.5 or greater than 2.0, a curability and mechanical properties etc. of the cured product may be impaired.

There are also no particular restrictions on a benzoxazine resin. Those represented by the following general formulae (3) and (4) can be preferably used.

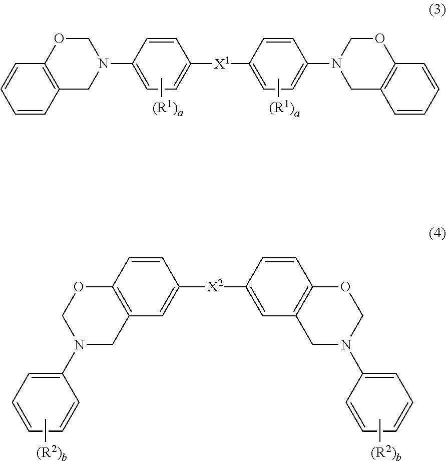

In the general formulae (3) and (4), each of X¹ and X² is independently selected from the group consisting of an alkylene group having 1 to 10 carbon atoms, —O—, —NH—, —S—, SP₂— and a single bond. Each of R¹ and R² independently represents a hydrogen atom or a hydrocarbon group having 1 to 6 carbon atoms. Each of a and b independently represents an integer of 0 to 4.

When the above phenolic resin and benzoxazine resin are used in combination, a preferable compounding ratio thereof as a mass ratio is (phenolic resin) : (benzoxazine resin)=50:50 to 10:90.

As for a ratio among the components (A), (D) and (E), it is preferred that a ratio of component (A) : component (D)+component (E), as a mass ratio, be 100:0 to 10:90. When the amount of the component (A) is small, tracking resistance and dielectric property will be impaired.

### (F) Mold Release Agent

A mold release agent can be added to the heat-curable maleimide resin composition of the invention which is used for semiconductor encapsulation. The mold release agent as a component (F) is added to improve a mold releasability at the time of performing molding. There are no restrictions on such mold release agent, as long as the mold release agent employed is that generally used in a heat-curable epoxy resin composition. While examples of the mold release agent include a natural wax (e.g. carnauba wax and rice wax) and a synthetic wax (e.g. acid wax, polyethylene wax and fatty acid ester), carnauba wax is preferred in terms of the mold releasability of the cured product.

It is preferred that the component (F) be added in an amount of 0.05 to 5.0% by mass, particularly preferably 1.0 to 3.0% by mass, with respect to the sum total of the components (A), (D) and (E). When such amount of the component (F) added is smaller than 0.05% by mass, the cured product of the composition of the invention may not exhibit a sufficient mold releasability. When the amount of the component (F) added is greater than 5.0% by mass, the composition of the invention may bleed out, and the cured product of the composition may exhibit an adhesion failure, for example.

### (G) Flame Retardant

A flame retardant can be added to the heat-curable maleimide resin composition of the invention which is used for semiconductor encapsulation, for the purpose of improving a flame retardancy. There are no particular restrictions on such flame retardant, and any known flame retardant may be used. For example, there may be used a phosphazene compound, a silicone compound, a zinc molybdate-supported talc, a zinc molybdate-supported zinc oxide, an aluminum hydroxide, a magnesium hydroxide, a molybdenum oxide and an antimony trioxide. Any one of these flame retardants may be used singularly, or two or more kinds of them may be used in combination. The flame retardant(s) is added in an amount of 2 to 20 parts by mass, preferably 3 to 10 parts by mass, per the sum total of 100 parts by mass of the components (A), (D) and (E).

### (H) Coupling Agent

A coupling agent such as a silane coupling agent and a titanate coupling agent can be added to the heat-curable maleimide resin composition of the invention which is used for semiconductor encapsulation, for the purpose of, for example, improving a bonding strength between the resin ingredients in the components (A), (D) and/or (E); and the inorganic filler as the component (B), and improving an adhesiveness between such resin ingredients and a metal lead frame.

Examples of such coupling agent include an epoxy functional alkoxysilane (e.g. γ-glycidoxypropyltrimethoxysilane, y-glycidoxypropylmethyldiethoxysilane and β-(3,4-epoxycyclohexyl)ethyltrimethoxysilane), a mercapto functional alkoxysilane (e.g. γ-mercaptopropyltrimethoxysilane) and an amine functional alkoxysilane (e.g. γ-aminopropyltrimethoxysilane and N-2-(aminoethyl)-3-aminopropyltrimethoxysilane).

The amount of the coupling agent added and a surface treatment method thereof may be those derived from a common procedure(s).

Further, the inorganic filler may be treated with the coupling agent in advance; or the composition may be produced while performing surface treatment by adding the coupling agent as the component (H) at the time of kneading the resin ingredients in the components (A), (D) and/or (E) together with the inorganic filler as the component (B).

It is preferred that the component (H) be contained in an amount of 0.1 to 8.0% by mass, particularly preferably 0.5 to 6.0% by mass, per the sum total of the components (A), (D) and (E). When such amount of the component (H) is smaller than 0.1% by mass, an insufficient adhesion effect to a base material may be observed. When the amount of the component (H) is greater than 8.0% by mass, a viscosity may extremely decrease such that voids may occur.

### Other Additives

If necessary, various types of additives may further be added to the heat-curable maleimide resin composition of the invention which is used for semiconductor encapsulation. On the premise that the effects of the present invention shall not be impaired, the additive(s) added may, for example, be an organopolysiloxane, a silicone oil, a thermoplastic resin, a thermoplastic elastomer, an organic synthetic rubber, a light stabilizer, a pigment and/or a dye, for the purpose of improving resin properties; or, for example, be an ion trapping agent for the purpose of improving electrical properties. A fluorine-containing material or the like may further be added for the purpose of improving the dielectric property.

### Production Method

There are no particular restrictions on a method for producing the composition of the present invention. For example, the components (A) to (C) and other components, if necessary, are to be blended together at given compounding ratios. Next, a mixer or the like is used to thoroughly and uniformly mix these components, followed by melting and mixing them with, for example, a heat roller, a kneader or an extruder. A product thus obtained is then cooled to be solidified, and is later crushed into pieces of an appropriate size. The resin composition thus obtained can be used as an encapsulation material.

As the most general method for molding the resin composition, there can be listed a transfer molding method and a compression molding method. In a transfer molding method, a transfer molding machine is used to perform molding under a molding pressure of 5 to 20 N/mm² and at molding temperature of 120 to 190° C. for a molding period of 30 to 500 sec, preferably at a molding temperature of 150 to 185° C. for a molding period of 30 to 180 sec. Further, in a compression molding method, a compression molding machine is used to perform molding at a molding temperature of 120 to 190° C. for a molding period of 30 to 600 sec, preferably at a molding temperature of 130 to 160° C. for a molding period of 120 to 300 sec. Moreover, in each molding method, post curing may further be performed at 150 to 225° C. for 0.5 to 20 hours.

If produced by the above method, the cured product of the heat-curable maleimide resin composition of the invention which is used for semiconductor encapsulation shall exhibit an excellent tracking resistance and an excellent dielectric property. The heat-curable maleimide resin composition of the invention which is used for semiconductor encapsulation, is especially suitable for encapsulating, for example, thin and downsized semiconductors, various types of in-car modules and materials for high frequencies.

### Working Example

The present invention is described in detail hereunder with reference to working and comparative examples. However, the present invention is not limited to the following working examples.

### (A) Maleimide Compound

(A-1) Maleimide compound-1 represented by the following formula (BMI-2500 by Designer Molecules Inc.)

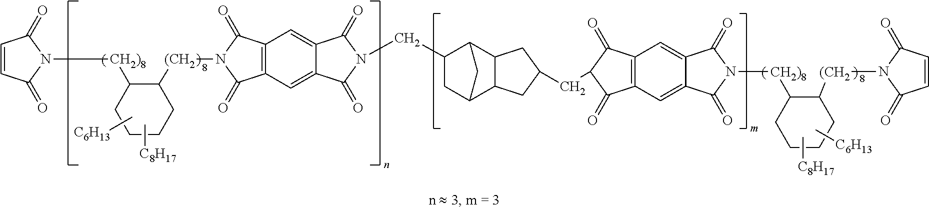

(A-2) Maleimide compound-2 represented by the following formula (BMI-3000 by Designer Molecules Inc.)

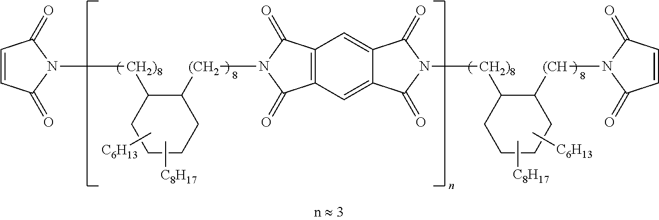

(A-3) 4,4′-diphenylmethanebismaleimide (BMI-1000 by Daiwa Fine Chemicals Co., Ltd.) (used in comparative examples)

### (B) Inorganic Filler

(B-1) Molten spherical silica (RS-8225H/53C by TATSUMORI LTD.; average particle size 13 μm)

### (C) Curing Accelerator

(C-1) Peroxide (PERCUMYL D by NOF CORPORATION)

(C-2) Imidazole-based catalyst (1B2PZ by SHIKOKU CHEMICALS CORPORATION)

### (D) Epoxy Resin

(D-1) Multifunctional epoxy resin (EPPN-501H by Nippon Kayaku Co., Ltd.; epoxy equivalent: 165)

(D-2) Dicyclopentadiene-type epoxy resin (HP-7200 by DIC; epoxy equivalent 259)

### (E) Curing Agent

(E-1) Phenol novolac resin (TD-2131 by DIC; phenolic hydroxyl group equivalent: 104)

(E-2) Benzoxazine resin (P-d type by SHIKOKU CHEMICALS CORPORATION; benzoxazine equivalent: 217)

### (F) Mold Release Agent

(F-1) Carnauba wax (TOWAX-131 by TOA KASEI CO., LTD.)

### Working Examples 1 to 7; Comparative Examples 1 to 4

The components in each example were melted and mixed together at the compounding ratios (parts by mass) shown in Table 1, followed by cooling and then crushing a product thus prepared so as to obtain a resin composition. The following properties of each composition were evaluated. The results thereof are shown in Table 1.

### Spiral Flow Value

A mold manufactured in accordance with the EMMI standard was used to measure a spiral flow value of a molded body of the above resin composition under a condition(s) of: molding temperature 175° C.; molding pressure 6.9 N/mm²; molding period 120 sec.

### Bending Strength, Bending Elastic Modulus

A mold manufactured in accordance with JIS K 6911:2006 was used to obtain a cured product of the above resin composition under a condition(s) of: molding temperature 175° C.; molding pressure 6.9 N/mm²; molding period 120 sec. The cured product was then subjected to post curing at 180° C. for four hours.

A bending strength and bending elastic modulus of a specimen prepared from the post-cured cured product were then measured at room temperature (25° C.) in accordance with JIS K6911:2006.

### Tracking Resistance Property (CTI) Test

A circular plate having a thickness of 3 mm and a diameter of 50 mm was molded under a condition(s) of: molding temperature 175° C.; molding pressure 6.9 N/mm²; molding period 120 sec. The cured product was then subjected to post curing at 180° C. for four hours. This cured product was then subjected to a tracking resistance property test that was performed by a method described in JIS C 2134 (IEC60112). A tracking resistance voltage was measured as follows. That is, in an evaluation test of five pieces of the cured product i.e. n=5, 50 or more droplets of a 0.1% ammonium chloride aqueous solution were delivered, and measured was the maximum voltage at which all the cured products had withstood the test without breakage.

### Water Absorption Rate

A circular plate having a thickness of 3 mm and a diameter of 50 mm was molded under a condition(s) of: molding temperature 175° C.; molding pressure 6.9 N/mm²; molding period 120 sec. The cured product was then treated at 121° C. under a saturated water vapor of 2.1 atm for 24 hours, and a water absorption rate was later calculated based on a rate of increase in the weight of the cured product that was observed before and after the treatment.

### Relative Permittivity, Dielectric Tangent

A 70-mm squared molded piece having a thickness of 1 mm was prepared under a condition(s) of: molding temperature 175° C.; molding pressure 6.9 N/mm²; molding period 120 sec. A network analyzer (E5063-2D5 by Keysight Technologies) and a stripline (by KEYCOM Corporation) were then connected to the molded piece to measure a relative permittivity and dielectric tangent thereof at 1.0 GHz.

As shown in Table 1, the cured products of the composition of the present invention exhibited higher tracking resistance and smaller values of relative permittivity and dielectric tangent. Thus, the composition of the present invention is useful as a material for encapsulating a semiconductor device.

TABLE 1

| Composition content | | | | Working example | | | | | | | Comparative example | | | |
|---|---|---|---|---|---|---|---|---|---|---|---|---|---|---|
| table (part by mass) | | | | 1 | 2 | 3 | 4 | 5 | 6 | 7 | 1 | 2 | 3 | 4 |
| (A) | Maleimide | BMI-2500 | A-1 | 100.0 | | 50.0 | | 20.0 | | | | | | |
| | compound | BMI-3000 | A-2 | | 100.0 | | 50.0 | | 20.0 | 50.0 | | | | |
| | | BMI-1000 | A-3 | | | | | | | | | | 100.0 | 50.0 |
| (B) | Inorganic | RS-8225H/ | B-1 | 590.0 | 590.0 | 590.0 | 590.0 | 590.0 | 590.0 | 590.0 | 590.0 | 590.0 | 590.0 | 590.0 |
| | filler | 53C | | | | | | | | | | | | |
| (C) | Curing | PERCUMYL | C-1 | 2.0 | 2.0 | 1.0 | 1.0 | 0.2 | 0.2 | | | | 2.0 | 1.0 |
| | accelerator | D | | | | | | | | | | | | |
| | | 1B2PZ | C-2 | | | 0.3 | 0.3 | 0.4 | 0.4 | 1.0 | 0.5 | 0.5 | | 0.3 |
| (D) | Epoxy | EPPN-501H | D-1 | | | 28.2 | | 45.0 | | 22.0 | 56.3 | | | 28.2 |
| | resin | HP-7200 | D-2 | | | | 33.5 | | 53.4 | | | 66.9 | | |
| (E) | Curing | TD-2131 | E-1 | | | 21.8 | 16.5 | 35.0 | 26.6 | | 43.7 | 33.1 | | 21.8 |
| | agent | P-d type | E-2 | | | | | | | 28.0 | | | | |
| (F) | Mold | TOWAX- | F-1 | 1.5 | 1.5 | 1.5 | 1.5 | 1.5 | 1.5 | 1.5 | 1.5 | 1.5 | 1.5 | 1.5 |
| | release | 131 | | | | | | | | | | | | |
| | agent | | | | | | | | | | | | | |

| | | | | | | | | | | | | | |
|---|---|---|---|---|---|---|---|---|---|---|---|---|---|
| Eval- | Spiral flow | inch | 30 | 32 | 35 | 36 | 35 | 36 | 28 | 36 | 41 | 12 | 25 |
| uation | Bending strength | MPa | 90 | 95 | 115 | 105 | 118 | 116 | 102 | 118 | 120 | 100 | 100 |
| result | Bending elastic modulus | MPa | 10000 | 9600 | 12500 | 12600 | 16500 | 16500 | 9100 | 20000 | 19000 | 25000 | 23000 |
| | Tracking resistance | V | >600 | >600 | 600 | >600 | 550 | 600 | >600 | 400 | 500 | 550 | 500 |
| | Water absorption rate | % | 0.3 | 0.3 | 0.4 | 0.3 | 0.5 | 0.5 | 0.3 | 0.8 | 0.7 | 0.8 | 0.8 |
| | Relative permittivity | | 2.8 | 2.2 | 3.0 | 2.7 | 3.2 | 2.9 | 2.7 | 3.9 | 3.7 | 3.6 | 3.7 |
| | Dielectric tangent | | 0.003 | 0.002 | 0.004 | 0.003 | 0.005 | 0.004 | 0.003 | 0.010 | 0.009 | 0.008 | 0.009 |

What is claimed is:

1. A heat-curable maleimide resin composition for semiconductor encapsulation, comprising:
(A) a maleimide compound being solid at 25° C., and having, per molecule, at least one dimer acid backbone, at least one linear alkylene group having not less than 6 carbon atoms, and at least two maleimide groups;
(B) an inorganic filler; and
(C) a curing accelerator.

2. The heat-curable maleimide resin composition for semiconductor encapsulation according to claim 1, further comprising an epoxy resin as a component (D).

3. The heat-curable maleimide resin composition for semiconductor encapsulation according to claim 2, further comprising a curing agent as a component (E).

4. The heat-curable maleimide resin composition for semiconductor encapsulation according to claim 3, wherein the curing agent as the component (E) is a phenolic resin and/or a benzoxazine resin.

5. The heat-curable maleimide resin composition for semiconductor encapsulation according to claim 1, wherein the maleimide compound as the component (A) is represented by the following general formulae (1) and/or (2): 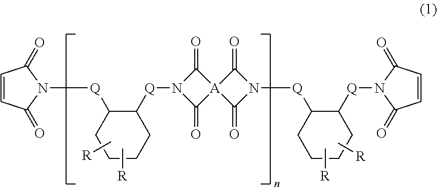
wherein A represents a tetravalent organic group having an aromatic ring or aliphatic ring; Q represents a linear alkylene group having not less than 6 carbon atoms; each R independently represents a linear or branched alkyl group having not less than 6 carbon atoms; n represents a number of 1 to 10, 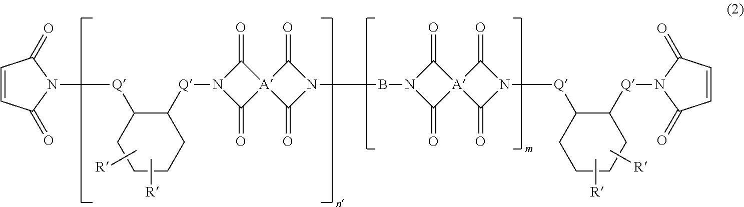
wherein A′ represents a tetravalent organic group having an aromatic ring or aliphatic ring; B represents an alkylene chain having 6 to 18 carbon atoms and a divalent aliphatic ring that may contain a hetero atom; Q′ represents a linear alkylene group having not less than 6 carbon atoms;
each R′ independently represents a linear or branched alkyl group having not less than 6 carbon atoms; n′ represents a number of 1 to 10; m represents a number of 1 to 10.

6. The heat-curable maleimide resin composition for semiconductor encapsulation according to claim 2, wherein the maleimide compound as the component (A) is represented by the following general formulae (1) and/or (2): 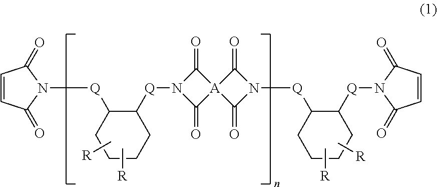
wherein A represents a tetravalent organic group having an aromatic ring or aliphatic ring; Q represents a linear alkylene group having not less than 6 carbon atoms; each R independently represents a linear or branched alkyl group having not less than 6 carbon atoms; n represents a number of 1 to 10, 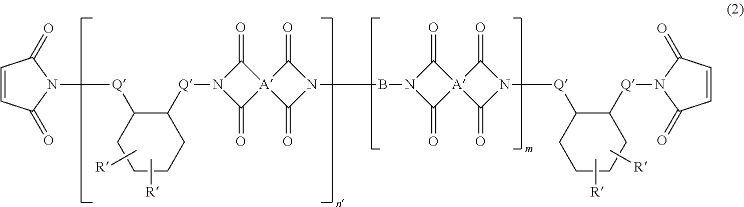
wherein A′ represents a tetravalent organic group having an aromatic ring or aliphatic ring; B represents an alkylene chain having 6 to 18 carbon atoms and a divalent aliphatic ring that may contain a hetero atom; Q′ represents a linear alkylene group having not less than 6 carbon atoms;
each R′ independently represents a linear or branched alkyl group having not less than 6 carbon atoms; n′ represents a number of 1 to 10; m represents a number of 1 to 10.

7. The heat-curable maleimide resin composition for semiconductor encapsulation according to claim 3, wherein the maleimide compound as the component (A) is represented by the following general formulae (1) and/or (2): 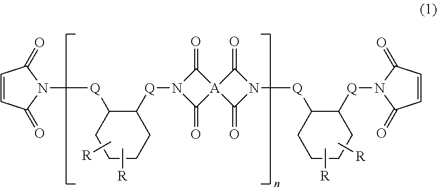
wherein A represents a tetravalent organic group having an aromatic ring or aliphatic ring; Q represents a linear alkylene group having not less than 6 carbon atoms; each R independently represents a linear or branched alkyl group having not less than 6 carbon atoms; n represents a number of 1 to 10, 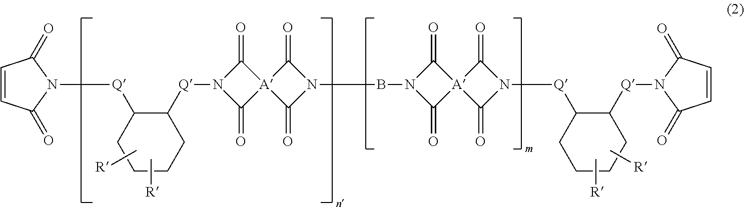
wherein A′ represents a tetravalent organic group having an aromatic ring or aliphatic ring; B represents an alkylene chain having 6 to 18 carbon atoms and a divalent aliphatic ring that may contain a hetero atom; Q′ represents a linear alkylene group having not less than 6 carbon atoms;
each R′ independently represents a linear or branched alkyl group having not less than 6 carbon atoms; n′ represents a number of 1 to 10; m represents a number of 1 to 10.

8. The heat-curable maleimide resin composition for semiconductor encapsulation according to claim 4, wherein the maleimide compound as the component (A) is represented by the following general formulae (1) and/or (2): 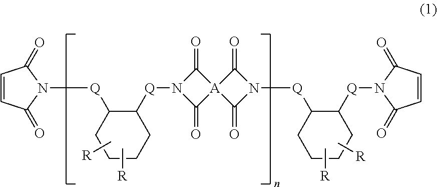
wherein A represents a tetravalent organic group having an aromatic ring or aliphatic ring; Q represents a linear alkylene group having not less than 6 carbon atoms; each R independently represents a linear or branched alkyl group having not less than 6 carbon atoms; n represents a number of 1 to 10, 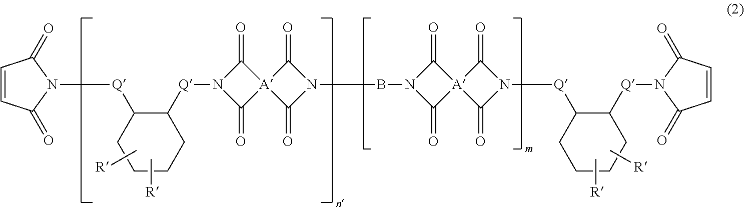
wherein A′ represents a tetravalent organic group having an aromatic ring or aliphatic ring; B represents an alkylene chain having 6 to 18 carbon atoms and a divalent aliphatic ring that may contain a hetero atom; Q′ represents a linear alkylene group having not less than 6 carbon atoms;
each R′ independently represents a linear or branched alkyl group having not less than 6 carbon atoms; n′ represents a number of 1 to 10; m represents a number of 1 to 10.

9. The heat-curable maleimide resin composition for semiconductor encapsulation according to claim 5, wherein each of A in the general formula (1) and A′ in the general formula (2) is represented by any one of the following structures: 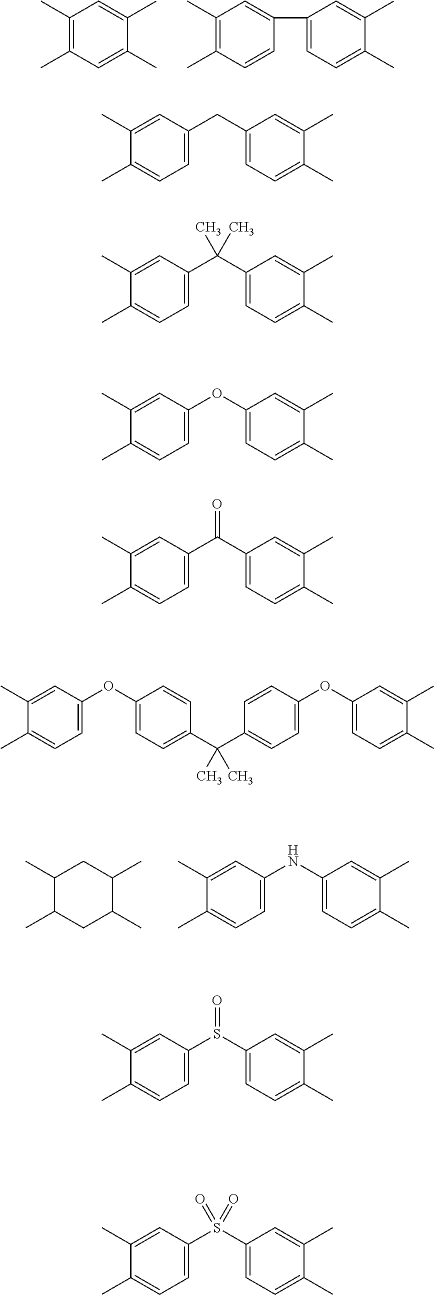
wherein bonds in the above structural formulae that are yet unbonded to substituent groups are to be bonded to carbonyl carbons forming cyclic imide structures in the general formulae (1) and (2).

10. The heat-curable maleimide resin composition for semiconductor encapsulation according to claim 6, wherein each of A in the general formula (1) and A′ in the general formula (2) is represented by any one of the following structures: 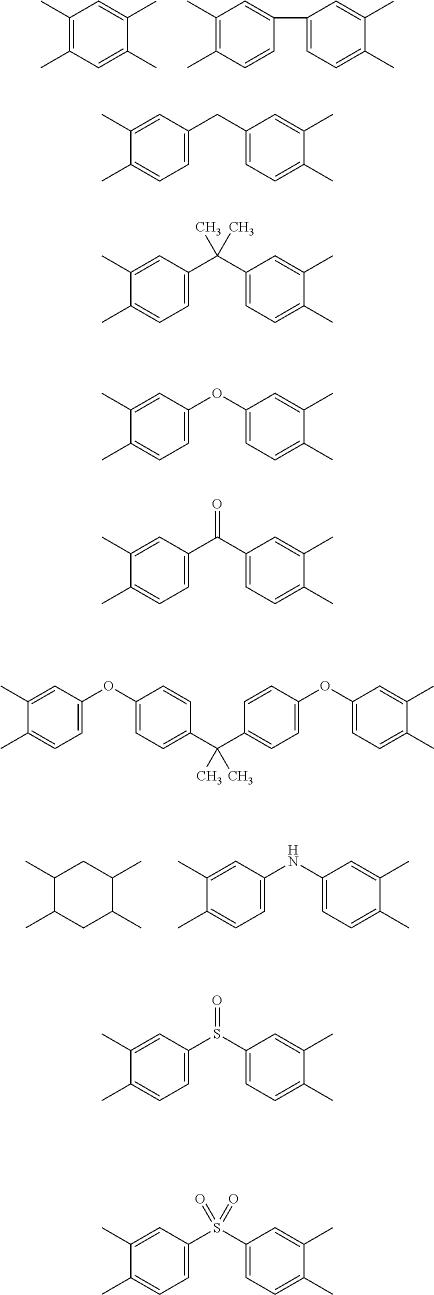
wherein bonds in the above structural formulae that are yet unbonded to substituent groups are to be bonded to carbonyl carbons forming cyclic imide structures in the general formulae (1) and (2).

11. The heat-curable maleimide resin composition for semiconductor encapsulation according to claim 7, wherein each of A in the general formula (1) and A′ in the general formula (2) is represented by any one of the following structures: 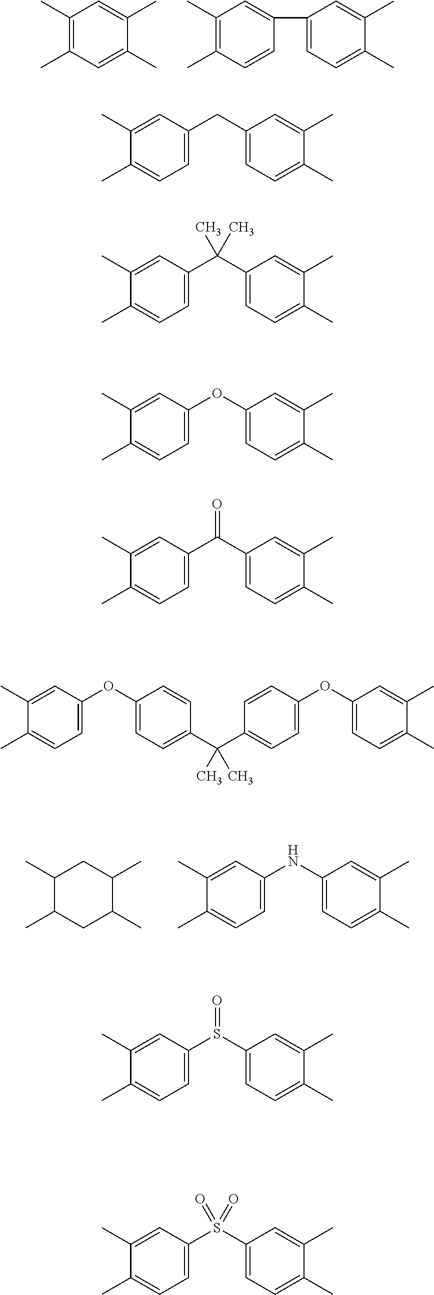
wherein bonds in the above structural formulae that are yet unbonded to substituent groups are to be bonded to carbonyl carbons forming cyclic imide structures in the general formulae (1) and (2).

12. The heat-curable maleimide resin composition for semiconductor encapsulation according to claim 8, wherein each of A in the general formula (1) and A′ in the general formula (2) is represented by any one of the following structures: 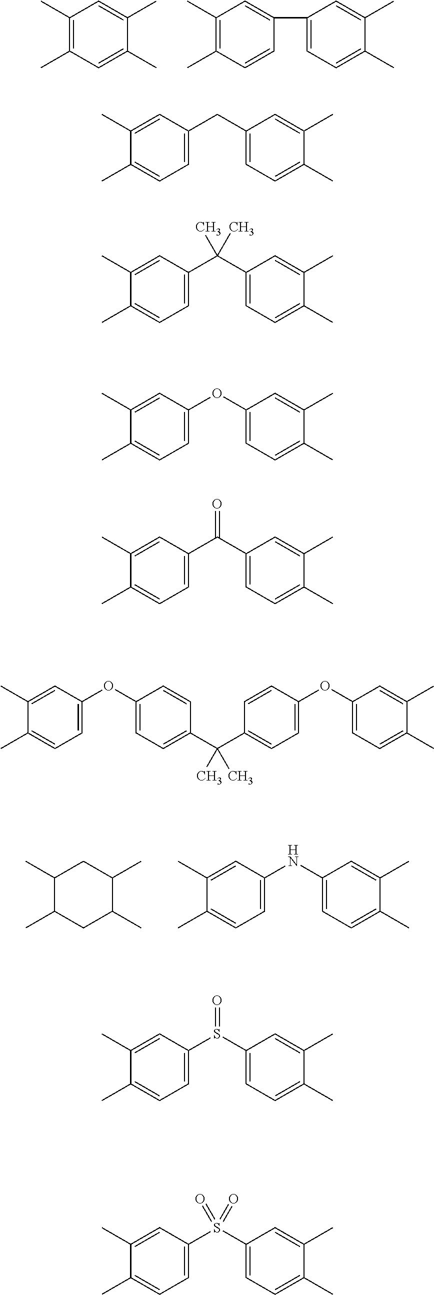
wherein bonds in the above structural formulae that are yet unbonded to substituent groups are to be bonded to carbonyl carbons forming cyclic imide structures in the general formulae (1) and (2).

13. A semiconductor device encapsulated by a cured product of the heat-curable maleimide resin composition for semiconductor encapsulation according to claim 1.
